(19) United States
(12) Patent Application Publication
(10) Pub. No.: US 2025/0087599 A1
(43) Pub. Date: Mar. 13, 2025

(54) SEMICONDUCTOR PACKAGE

(71) Applicant: SAMSUNG ELECTRONICS CO., LTD., SUWON-SI (KR)

(72) Inventor: Seung Hyun BAIK, Suwon-si (KR)

(21) Appl. No.: 18/627,687

(22) Filed: Apr. 5, 2024

(30) Foreign Application Priority Data
Sep. 13, 2023 (KR) 10-2023-0121487
Oct. 26, 2023 (KR) 10-2023-0144289

(51) Int. Cl. H01L 23/00; H01L 23/31; H01L 25/065; H01L 25/16

(52) U.S. Cl. CPC H01L 23/562; H01L 23/3128; H01L 25/16; H10D 1/68; H01L 24/32; H01L 24/48; H01L 24/73; H01L 25/0657; H01L 2224/32145; H01L 2224/32225; H01L 2224/48145; H01L 2224/48227; H01L 2224/73265; H01L 2225/06506; H01L 2225/0651; H01L 2225/06562

(57) ABSTRACT

A semiconductor package includes a package substrate. A ceramic electronic component is electrically connected to the package substrate. The ceramic electronic component includes a main body having a main body upper surface and a first electrode disposed on a first side of the main body. The first side of the main body includes a first upper area disposed on the main body upper surface. A second electrode is disposed on an opposite second side of the main body. The second side of the main body includes a second upper area disposed on the main body upper surface. The second upper area is spaced apart from the first upper area. A protection unit is disposed on the main body upper surface and is positioned between the first and second upper areas. A mold unit seals the ceramic electronic component and the protection unit.

### CROSS-REFERENCE TO RELATED APPLICATION

This application claims priority under 35 U.S.C. § 119 to Korean Patent Application No. 10-2023-0121487, filed on Sep. 13, 2023 in the Korean Intellectual Property Office (KIPO) and Korean Patent Application No. 10-2023-0144289, filed on Oct. 26, 2023 in KIPO, the disclosures of which are incorporated by reference in their entireties herein.

### 1. TECHNICAL FIELD

The present disclosure relates to a semiconductor package.

### 2. DISCUSSION OF RELATED ART

As electronic components have become increasingly miniaturized and lightweight, the size of the semiconductor package mounted on the electronic component should also be reduced. However, while the number and size of semiconductor chips in the semiconductor package are increasing, the area of the package remains limited. Therefore, the semiconductor chips should be efficiently arranged within the limited area of the semiconductor package.

When a passive element is disposed in the semiconductor package, the residue and moisture of a specific flux may remain on an upper surface of a multi-layer ceramic capacitor (MLCC) which results in an interfacial delamination phenomenon between the passive element and an epoxy molding compound (EMC) layer.

### BRIEF SUMMARY

An object of the present disclosure is to provide a semiconductor package in which reliability is increased.

The objects of the present disclosure are not limited to those mentioned above and additional objects of the present disclosure, which are not mentioned herein, will be clearly understood by those skilled in the art from the following description of the present disclosure.

According to an embodiment of the present disclosure, a semiconductor package includes a package substrate. A ceramic electronic component is electrically connected to the package substrate. The ceramic electronic component includes a main body having a main body upper surface and a first electrode disposed on a first side of the main body. The first side of the main body includes a first upper area disposed on the main body upper surface. A second electrode is disposed on a second side of the main body that is opposite to the first side of the main body. The second side of the main body includes a second upper area disposed on the main body upper surface. The second upper area is spaced apart from the first upper area. A protection unit is disposed on the main body upper surface and is positioned between the first upper area and the second upper area. A mold unit seals the ceramic electronic component and the protection unit.

According to an embodiment of the present disclosure, a method for fabricating a semiconductor package includes disposing a first semiconductor chip in a first area of a package substrate. A second semiconductor chip is disposed in a second area of the package substrate. The second area of the package substrate is spaced apart from the first area of the package substrate. A first multi-layer ceramic capacitor is disposed in a third area of the package substrate. The third area of the package substrate is spaced apart from the first and second areas of the package substrate. A second multi-layer ceramic capacitor is disposed in a fourth area of the package substrate. The fourth area of the package substrate is spaced apart from the first to third areas of the package substrate. A first protection unit is disposed on an upper surface of the first multi-layer ceramic capacitor. A second protection unit is disposed on an upper surface of the second multi-layer ceramic capacitor. A mold unit is generated sealing the first multi-layer ceramic capacitor, the second multi-layer ceramic capacitor, the first semiconductor chip, the second semiconductor chip, the first protection unit and the second protection unit.

According to an embodiment of the present disclosure, a semiconductor package includes a package substrate. A ceramic electronic component is electrically connected to the package substrate. The ceramic electronic component includes a main body having a main body upper surface and a first electrode disposed on a first side of the main body. The first side of the main body includes a first upper area positioned on the main body upper surface, and a second electrode disposed on a second side of the main body that is opposite to the first side of the main body. The second side of the main body includes a second upper area positioned on the main body upper surface. The second upper area is spaced apart from the first upper area. At least one semiconductor chip. A protection unit is disposed on the main body upper surface and positioned between the first upper area and the second upper area. A mold unit seals the ceramic electronic component and the protection unit.

### BRIEF DESCRIPTION OF THE DRAWINGS

FIG. 1 is a view illustrating only some elements of a semiconductor package according to an embodiment of the present disclosure.

FIGS. 2 and 3 are views illustrating a method for fabricating a semiconductor package according to some embodiments of the present disclosure.

FIGS. 4 to 6 are views illustrating an effect of a semiconductor package around A of FIG. 1.

FIGS. 7 to 13 are views illustrating only some elements of a semiconductor package according to some embodiments of the present disclosure.

FIG. 14 is a view illustrating only some elements of a semiconductor package according to an embodiment of the present disclosure.

FIG. 15 is a block diagram illustrating a semiconductor package according to some embodiments of the present disclosure.

FIG. 16 is a block diagram illustrating a memory card including a semiconductor package according to an embodiment of the present disclosure.

FIG. 17 is a block diagram illustrating an information processing system to which a semiconductor package according to an embodiment of the present disclosure is applied.

### DETAILED DESCRIPTION OF EMBODIMENTS

Hereinafter, non-limiting embodiments of the present disclosure will be described in detail with reference to the accompanying drawings. The same reference numerals will be used for the same elements on the drawing, and a repeated description of the corresponding elements will be omitted.

Hereinafter, a semiconductor package according to some embodiments of the present disclosure will be described with reference to the accompanying drawings.

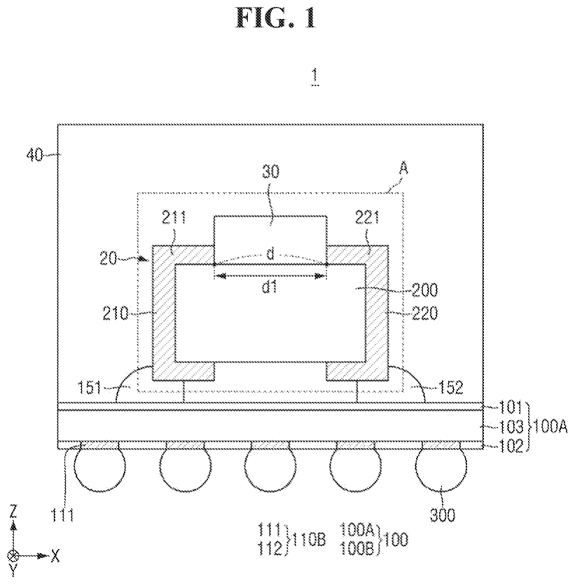

FIG. 1 is a view illustrating only some elements of a semiconductor package according to an embodiment.

Referring to FIG. 1, a semiconductor package 1 according to an embodiment of the present disclosure may include a package substrate 100, a ceramic electronic component 20, a protection unit 30 and a mold unit 40.

The package substrate 100 may be a substrate for a semiconductor package. In an embodiment, the package substrate 100 may be, for example, a printed circuit board (PCB), a lead frame (LF), a ceramic substrate, a silicon wafer or a wiring substrate. The printed circuit board may include a rigid PCB, a flexible PCB or a rigid flexible PCB

The package substrate 100 may extend in a first direction X and a second direction Y, respectively. In an embodiment, the first direction X and the second direction Y may be parallel with an upper surface of the package substrate 100 and cross each other. For example, in an embodiment, the first and second directions X, Y may be perpendicular to each other. However, embodiments of the present disclosure are not necessarily limited thereto. A third direction Z may mean a direction crossing each of the first direction X and the second direction Y and perpendicular to the upper surface of the package substrate 100.

In an embodiment, the package substrate 100 may include an insulating structure 100A and a wiring structure 100B.

In an embodiment, the insulating structure 100A may include an upper passivation layer 101, a lower passivation layer 102 and an insulating layer 103. In an embodiment, the insulating layer 103 may be disposed between (e.g., directly therebetween) the upper passivation layer 101 and the lower passivation layer 102 (e.g., in the Z direction). The upper passivation layer 101 and the lower passivation layer 102 may be disposed on an upper surface and a lower surface of the insulating layer 103, respectively.

In an embodiment, the upper passivation layer 101 and the lower passivation layer 102 may include an organic material such as a photosensitive polymer. The photosensitive polymer may include at least one of, for example, a photosensitive polyimide, polybenzoxazole, a phenolic polymer or a benzocyclobutene-based polymer. The upper passivation layer 101 and the lower passivation layer 102 may include, for example, a photo imagable dielectric material. However, embodiments of the present disclosure are not necessarily limited thereto.

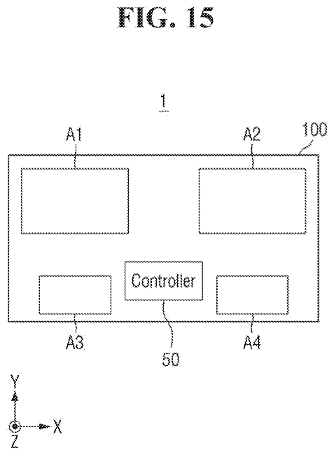

The wiring structure 100B may be disposed in the insulating structure 100A. In an embodiment, the wiring structure 100B may include a lower wiring pad 111 and an upper wiring pad (112 of FIG. 15) that will be described later. In an embodiment, a plurality of wiring pads and vias, which electrically connect the lower wiring pad 111 with the upper wiring pad 112, may be formed in the insulating layer 103. A detailed description of the upper wiring pad 112 will be described later.

The package substrate 100 may include an external connection terminal 300. In an embodiment, a plurality of external connection terminals 300 may be formed below the package substrate 100. The external connection terminal 300 may be disposed to be electrically connected to the package substrate 100. In an embodiment, the external connection terminal 300 may be in contact with (e.g., directly contact therewith) the lower wiring pad 111.

In some embodiments, the external connection terminal 300 may electrically connect a semiconductor package including the package substrate 100 to another semiconductor package. Alternatively, the external connection terminal 300 may electrically connect the semiconductor package including the package substrate 100 to another semiconductor device.

In the drawing, the external connection terminal 300 is shown as a solder ball. However, embodiments of the present disclosure are not necessarily limited thereto. For example, in some embodiments the external connection terminal 300 may be a solder bump, a grid array, a conductive tab or the like.

The ceramic electronic component 20 may be disposed on the package substrate 100. For example, in an embodiment the ceramic electronic component 20 may be a MLCC.

The ceramic electronic component 20 may include a main body 200, a first electrode 210 and a second electrode 220. In an embodiment, the main body 200 may be formed in a shape in which an internal electrode and a dielectric layer are alternately stacked.

The first electrode 210 and the second electrode 220 may be disposed on both sides of the main body 200 (e.g., in the X direction), respectively. The first electrode 210 and the second electrode 220 may be connected to the internal electrode.

In an embodiment, the first electrode 210 may be disposed on a first side of the main body 200, and may include a first upper area 211 on an upper surface of the main body 200. The first upper area 211 may cover a portion of the main body 200.

In an embodiment, the second electrode 220 may be disposed on the opposite second side of the main body 200, and may include a second upper area 221 different from the first upper area 211 on the upper surface of the main body 200. The first upper area 211 and the second upper area 221 may be spaced apart from each other (e.g., in the X direction). The second upper area 221 may cover a portion of the main body 200.

The first electrode 210 and the second electrode 220 of the ceramic electronic component 20 may be electrically connected to the package substrate 100 by a first solder 151 and a second solder 152.

The protection unit 30 may be disposed between the first upper area 211 and the second upper area 221 of the ceramic electronic component 20 (e.g., in the X direction).

For reference, a length used in the present disclosure is defined to mean the shortest length between two objects. In addition, a height of an element in the present disclosure is defined to mean a length measured in the third direction Z on a bottom surface of the element.

A length between the first upper area 211 and the second upper area 221 corresponds to d1. A length of a lower surface of the protection unit 30 corresponds to ‘d’.

In some embodiments, ‘d1’ and ‘d’ may be the same as each other. For example, the length of the lower surface of the protection unit 30 may be the same as the length between the first upper area 211 and the second upper area 221. Therefore, the protection unit 30 may entirely cover the upper surface of the main body 200 of the ceramic electronic component 20 that is in contact with the mold unit 40.

A height of the protection unit 30 may be greater than that of the first upper area 211 and the second upper area 221.

Although the protection unit 30 is shown as having a rectangular shape, embodiments of the present disclosure are not necessarily limited thereto and the shape of the protection unit 30 may vary. For example, in some embodiments the shape of the protection unit 30 may correspond to a chamfered shape having a bent edge.

In some embodiments, the protection unit 30 may be made of a thermosetting resin such as an epoxy resin. However, embodiments of the present disclosure are not necessarily limited thereto.

In some embodiments, an adhesive force between the protection unit 30 and the mold unit 40 may be greater than that between the first electrode 210 and the second electrode 220 and the mold unit 40.

In some embodiments, the mold unit 40 may integrally cover the protection unit 30 and the ceramic electronic component 20. The mold unit 40 may be disposed on an upper surface of the protection unit 30 and an upper surface of the ceramic electronic component 20. The mold unit 40 may be in contact with (e.g., direct contact therewith) the upper surface of the protection unit 30 and the upper surface of the ceramic electronic component 20, respectively.

In some embodiments, the mold unit 40 may include an insulating material. For example, the mold unit 40 may include a thermosetting resin such as an epoxy resin and a thermoplastic resin such as polyimide. In addition, for example, the mold unit 40 may include a molding material such as an Epoxy Molding Compound (EMC).

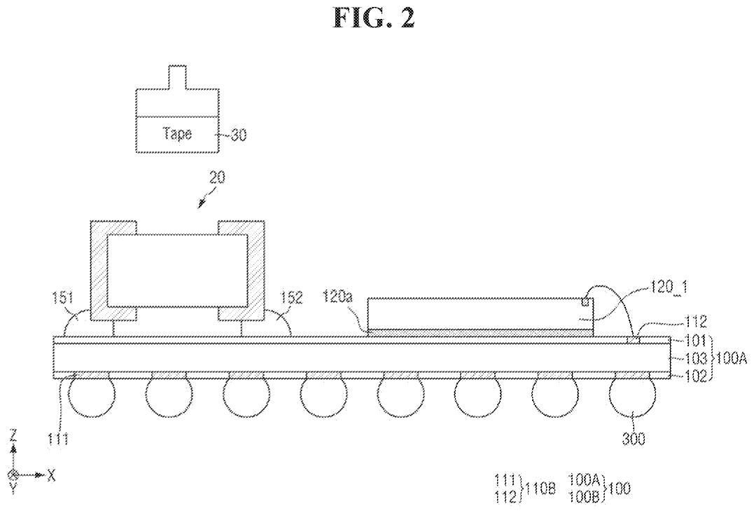

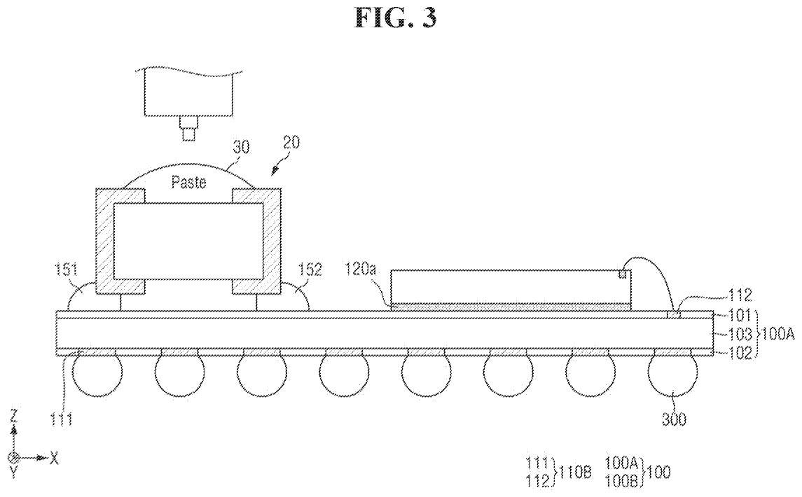

FIGS. 2 and 3 are views illustrating a method for fabricating a semiconductor package according to some embodiments of the present disclosure.

Referring to FIG. 2, the ceramic electronic component 20 and a first semiconductor chip 120_1 may be packaged on the package substrate 100, and the ceramic electronic component 20 and the first semiconductor chip 120_1 may be electrically connected to the package substrate 100 by a reflow process. After performance of the reflow process, a tape type protection unit 30 may be attached to the upper surface of the ceramic electronic component 20.

In an embodiment, after the protection unit 30 is formed, a deflux process for removing flux residue or other contamination from a surface of the substrate, a chip-stack process and a mold process may be performed.

Referring to FIG. 3, the ceramic electronic component 20 and the first semiconductor chip 120_1 may be packaged on the package substrate 100, and the ceramic electronic component 20 and the first semiconductor chip 120_1 may be electrically connected to the package substrate 100 by a reflow process.

In an embodiment, after the reflow process is performed, a non-conductive material, such as a thermosetting resin, for example, an epoxy resin may be coated on the upper surface of the ceramic electronic component 20 by a dispenser in the form of a paste.

In an embodiment, after the protection unit 30 is formed, a deflux process for removing flux residue or other contamination from a surface of the substrate, a chip-stack process and a mold process may be performed.

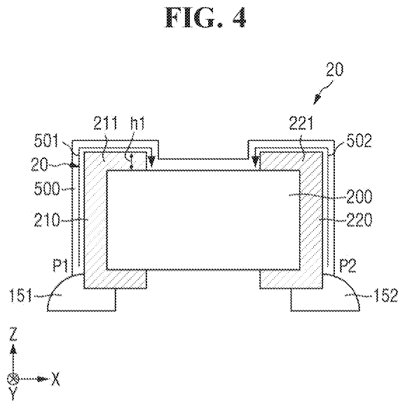

FIGS. 4 to 6 are views illustrating an effect of a semiconductor package around A of FIG. 1.

Referring to FIG. 4, in some embodiments, the ceramic electronic component 20 included in the semiconductor package 1 may be completely packaged by a surface mounting technology (SMT) and then residue of the flux may remain on the upper surface of the ceramic electronic component 20. The hardening of the mold unit 40 may be delayed due to the residue of the flux, and the bonding strength between the mold unit 40 and the ceramic electronic component 20 may be reduced.

When the bonding strength between the mold unit 40 and the ceramic electronic component 20 is reduced, stress may be increased on the interface between the mold unit 40 and the first and second electrodes 210 and 220 by a process subsequent to a packaging process by the surface mounting technology (SMT). Therefore, an interfacial delamination phenomenon may occur on the interface between the mold unit 40 and the first and second electrodes 210 and 220.

In some embodiments, an interface gap 500 may occur between the mold unit 40 and the first and second electrodes 210 and 220 due to the interfacial delamination phenomenon. The first solder 151 partially melted in accordance with a high temperature process (e.g., a reflow process) may move along a first path P1 of the interface gap 500. This is called a first permeation solder 501. Likewise, the second solder 152 partially melted in accordance with the high temperature process may move along a second path P2 of the interface gap 500. This is called a second permeation solder 502. When the first permeation solder 501 and the second permeation solder 502, which have moved along the interface gap 500, come into contact with each other (e.g., direct contact with each other), the first electrode 210 and the second electrode 220 may be short-circuited.

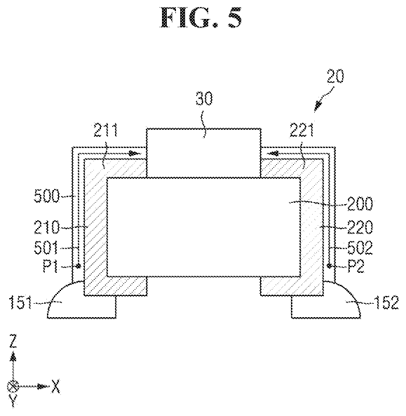

However, referring to FIG. 5, in some embodiments of the present disclosure, the protection unit 30 having a high level of adhesion with the mold unit 40 is included between the first electrode 210 and the second electrode 220. The protection unit 30 may prevent the occurrence of an interfacial delamination phenomenon on a surface where the protection unit 30 and the mold unit 40 are in contact with each other.

Therefore, the protection unit 30 may prevent the first permeation solder 501 and the second permeation solder 502, which have moved along the interface gap 500 between the first and second electrodes 210 and 220 and the mold unit 40, from being in contact with each other. Therefore, the first electrode 210 and the second electrode 220 may be prevented from being short-circuited.

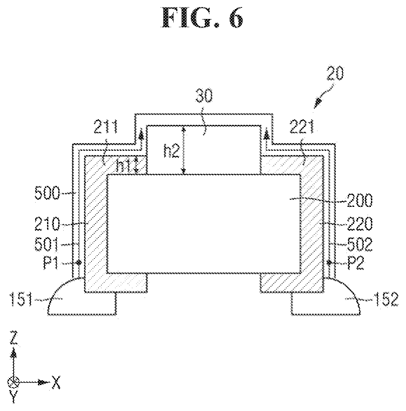

Referring to FIGS. 4 and 6, in some embodiments, a height of the first upper area 211 of the first electrode 210 may be h1. A height of the protection unit 30 may be h2. In some embodiments, h2 may be at least twice of h1.

Therefore, even though the interface gap 500 is extended between the protection unit 30 and the mold unit 40, a distance at which the first permeation solder 501 and the second permeation solder 502 should move along the interface gap 500 may be increased.

For example, referring to FIG. 4, the first permeation solder 501 moved to the end of the first upper area 211 along the first path P1 may move in a fourth direction-Z as much as h1. However, referring to FIG. 6, when the protection unit 30 is attached to the ceramic electronic component 20, the first permeation solder 501 moved to the end of the first upper area 211 along the first path P1 may move in the third direction Z as much as the difference between h2 and h1 (e.g., h2−h1).

Since h2 is at least twice of h1, the distance at which the first permeation solder 501 and the second permeation solder 502 should move to be in contact with each other (e.g., direct contact with each other) may be increased. Therefore, even though the interface gap 500 is extended between the protection unit 30 and the mold unit 40, the first electrode 210 and the second electrode 220 may be still prevented from being short-circuited.

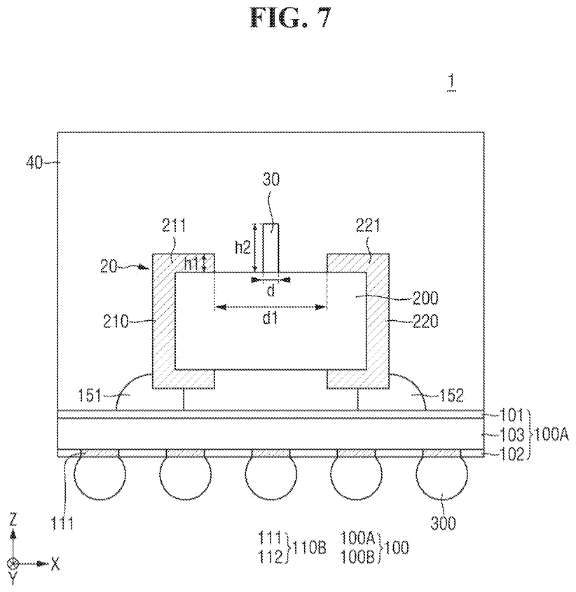

FIGS. 7 to 13 are views illustrating only some elements of a semiconductor package according to some embodiments of the present disclosure. For reference, FIGS. 7 to 12 are cross-sectional views corresponding to FIG. 1. For convenience of description, the same description as that made with reference to FIG. 1 may be omitted.

Referring to FIG. 7, the protection unit 30 may be disposed between the first upper area 211 and the second upper area 221 of the ceramic electronic component 20 (e.g., in the X direction).

A length between the first upper area 211 and the second upper area 221 corresponds to d1. The length of the lower surface of the protection unit 30 corresponds to ‘d’.

In some embodiments, a size of ‘d’ may be less than that of d1. For example, the length of the lower surface of the protection unit 30 may be less than the length between the first upper area 211 and the second upper area 221. Therefore, in an embodiment the protection unit 30 may cover only a portion of the upper surface of the main body 200 of the ceramic electronic component 20 that is in direct contact with the mold unit 40. For example, as shown in FIG. 7 sides of an uppermost portion of the first electrode 210 and sides of an uppermost portion of the second electrode 220 are not in direct contact with the protection unit 30.

The height h2 of the protection unit 30 may be greater than the height h1 of the first upper area 211 and the second upper area 221.

In FIG. 7, the edge of the protection unit 30 is shown as having a right angled shape. However, embodiments of the present disclosure are not necessarily limited thereto and the shape of the edge of the protection unit 30 may vary. For example, in some embodiments the protection unit 30 may include a chamfered shape having a bent edge.

In some embodiments, the protection unit 30 may be made of a thermosetting resin such as an epoxy resin. However, embodiments of the present disclosure are not necessarily limited thereto.

Similarly to that described with reference to FIG. 5, in some embodiments, an interfacial delamination phenomenon may occur on a surface where the mold unit 40 and the ceramic electronic component 20 come into contact with each other (e.g. direct contact with each other). The interface gap 500 may be included among the mold unit 40, the first electrode 210, the second electrode 220 and the main body 200 of the ceramic electronic component in accordance with the interfacial delamination phenomenon. The first solder 151 and the second solder 152, which are partially melted in accordance with a high-temperature process, may move along the interface gap 500. These solders are called the first permeation solder 501 and the second permeation solder 502, respectively.

In some embodiments, the protection unit 30 having a high level of adhesion with the mold unit 40 is included between the first electrode 210 and the second electrode 220. The protection unit 30 may prevent the occurrence of an interfacial delamination phenomenon on the surface where the protection unit 30 and the mold unit 40 come in contact with each other (e.g., direct contact with each other).

In addition, the protection unit 30 may block the first permeation solder 501 and the second permeation solder 502, which have moved along the interface gap 500, to prevent the first permeation solder 501 and the second permeation solder 502 from being in direct contact with each other. Therefore, the first electrode 210 and the second electrode 220 may be prevented from being short-circuited.

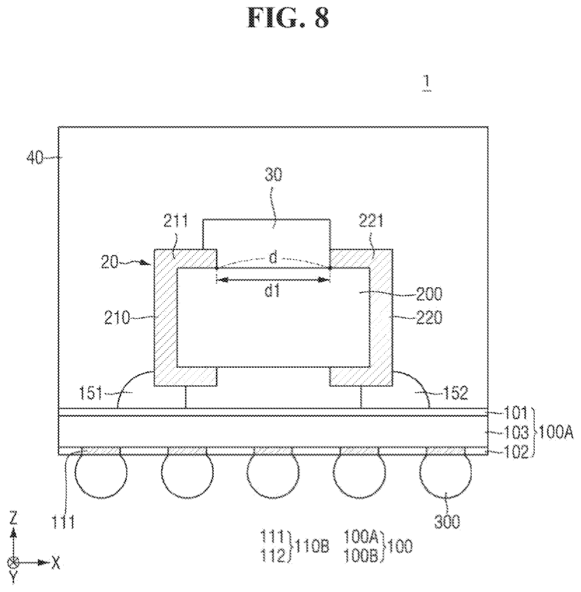

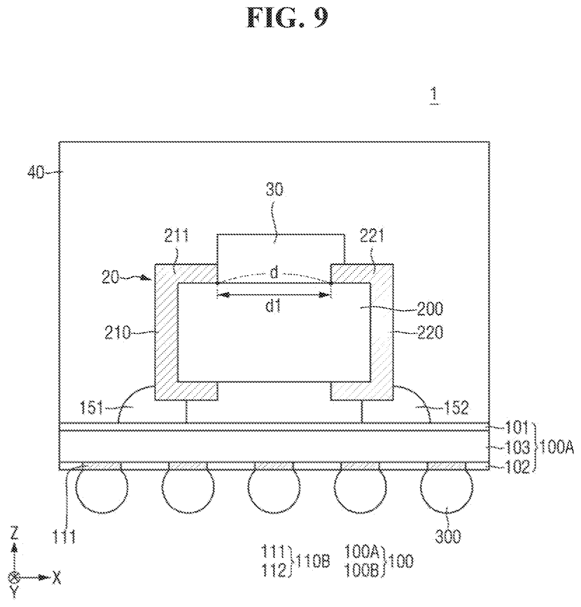

Referring to FIGS. 8 and 9, the protection unit 30 may be disposed between the first upper area 211 and the second upper area 221 of the ceramic electronic component 20 (e.g., in the X direction).

The length between the first upper area 211 and the second upper area 221 corresponds to d1. The length of the lower surface of the protection unit 30 corresponds to ‘d’.

In some embodiments, the size of ‘d’ may be the same as that of d1. For example, the length of the lower surface of the protection unit 30 may be the same as the length between the first upper area 211 and the second upper area 221. Therefore, the protection unit 30 may entirely cover the upper surface of the main body 200 of the ceramic electronic component 20 that is in direct contact with the mold unit 40.

Also, in some embodiments, the protection unit 30 may have a shape covering a portion of the first upper area 211 or the second upper area 221, such as a portion of an upper surface of the first upper area 211 or a portion of an upper surface of the second upper area 221.

In the drawing, the edge of the protection unit 30 is shown as having a right angled shape. However, embodiments of the present disclosure are not necessarily limited thereto and the shape of the edge of the protection unit 30 may vary. For example, in an embodiment the protection unit 30 may correspond to a chamfered shape having a bent edge.

In some embodiments, the protection unit 30 may be made of a thermosetting resin such as an epoxy resin. However, embodiments of the present disclosure are not necessarily limited thereto.

Similarly to that described with reference to FIG. 5, in some embodiments, the protection unit 30 having a high level of adhesion with the mold unit 40 is included between the first electrode 210 and the second electrode 220, whereby an interfacial delamination phenomenon may be prevented from occurring on the surface where the protection unit 30 and the mold unit 40 come in contact with each other (e.g., direct contact with each other).

The protection unit 30 may block the first permeation solder 501 and the second permeation solder 502, which have moved along the interface gap 500 between the first and second electrodes 210 and 220 and the mold unit 40. Therefore, the protection unit 30 may prevent the first permeation solder 501 and the second permeation solder 502 from being in direct contact with each other. Thus, the first electrode 210 and the second electrode 220 may be prevented from being short-circuited.

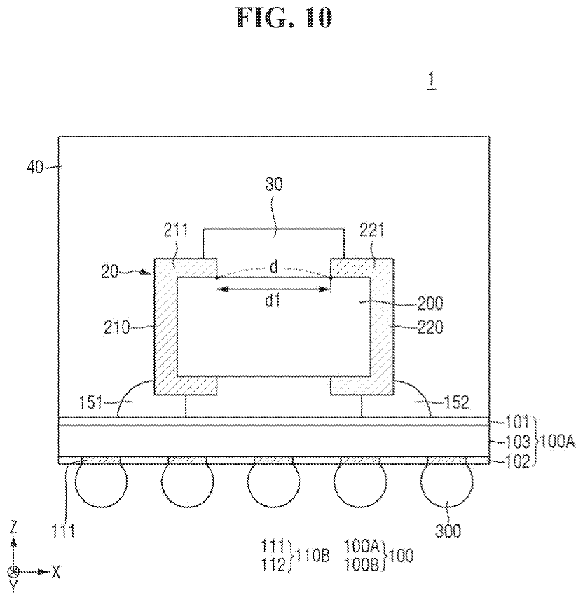

Referring to FIG. 10, the protection unit 30 may be disposed between the first upper area 211 and the second upper area 221 of the ceramic electronic component 20 (e.g., in the X direction).

The length between the first upper area 211 and the second upper area 221 corresponds to d1. The length of the lower surface of the protection unit 30 corresponds to ‘d’.

In some embodiments, the size of ‘d’ may be the same as that of d1. For example, the length of the lower surface of the protection unit 30 may be the same as the length between the first upper area 211 and the second upper area 221. Therefore, the protection unit 30 may entirely cover the upper surface of the main body 200 of the ceramic electronic component 20 that is in direct contact with the mold unit 40.

Also, in some embodiments, the protection unit may have a shape covering a portion of the first upper area 211 or the second upper area 221.

In the drawing, the edge of the protection unit 30 is shown as having a right angled shape. However, embodiments of the present disclosure are not necessarily limited thereto and the shape of the edge of the protection unit 30 may vary. For example, in an embodiment the protection unit 30 may include a chamfered shape having a bent edge.

In some embodiments, the protection unit 30 may be made of a thermosetting resin such as an epoxy resin. However, embodiments of the present disclosure are not necessarily limited thereto.

Similarly to that described with reference to FIG. 5, in some embodiments, the protection unit 30 having a high level of adhesion with the mold unit 40 is included between the first electrode 210 and the second electrode 220, whereby the protection unit 30 may prevent the occurrence of an interfacial delamination phenomenon on the surface where the protection unit 30 and the mold unit 40 come in contact with each other (e.g., direct contact with each other).

The protection unit 30 may block the first permeation solder 501 and the second permeation solder 502, which have moved along the interface gap 500 between the first and second electrodes 210 and 220 and the mold unit 40. Therefore, the first permeation solder 501 and the second permeation solder 502 may be prevented from being in direct contact with each other. Thus, the first electrode 210 and the second electrode 220 may be prevented from being short-circuited.

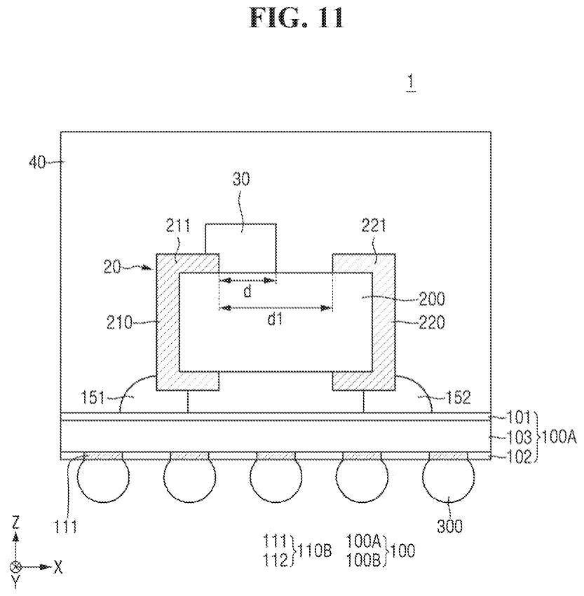

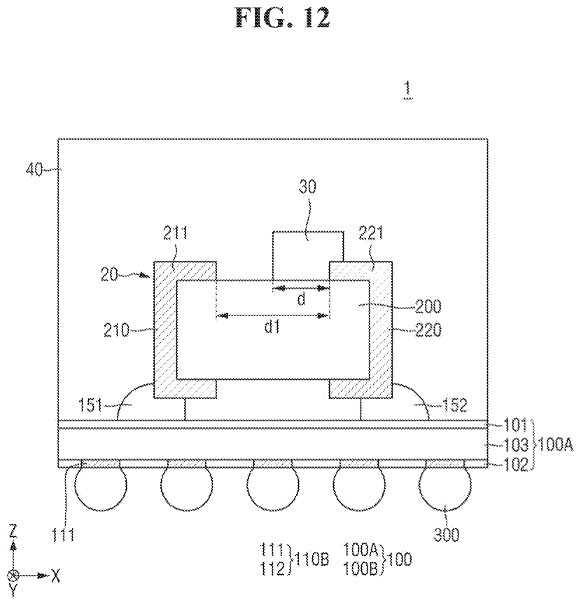

Referring to FIGS. 11 and 12, the protection unit 30 may be disposed between the first upper area 211 and the second upper area 221 of the ceramic electronic component 20 (e.g., in the X direction).

The length between the first upper area 211 and the second upper area 221 corresponds to d1. The length of the lower surface of the protection unit 30 corresponds to ‘d’.

In some embodiments, the size of ‘d’ may be less than that of d1. For example, the length of the lower surface of the protection unit 30 may be less than the length between the first upper area 211 and the second upper area 221. Therefore, the protection unit 30 may cover only a portion of the upper surface of the main body 200 of the ceramic electronic component 20 that is in contact with the mold unit 40 (e.g., direct contact therewith).

Also, in some embodiments, the protection unit 30 may have a shape covering a portion of the first upper area 211 or the second upper area 221. For example, in an embodiment shown in FIG. 11, the protection unit 30 may cover a portion of an upper surface of the first upper area 211 and be spaced apart from (e.g., not be in direct contact therewith) the second upper area 221, such as an inner side of the second upper area 221 which faces the first upper area 211. In an embodiment shown in FIG. 12, the protection unit 30 may cover a portion of an upper surface of the second upper area 221 and be spaced apart from (e.g., not be in direct contact therewith) the first upper area 211, such as an inner side of the first upper area 211 which faces the second upper area 221. Therefore, as shown in FIG. 11 the sides of an uppermost portion of the second electrode 220 may not be in direct contact with the protection unit 30. As shown in FIG. 12, the sides of an uppermost portion of the first electrode 210 may not be in direct contact with the protection unit 30.

In the drawing, the edge of the protection unit 30 is shown as having a right angled shape. However, embodiments of the present disclosure are not necessarily limited thereto and the shape of the edge of the protection unit 30 may vary. For example, in an embodiment the protection unit 30 may include a chamfered shape having a bent edge.

In some embodiments, the protection unit 30 may be made of a thermosetting resin such as an epoxy resin. However, embodiments of the present disclosure are not necessarily limited thereto.

Similarly to that described with reference to FIG. 5, in some embodiments, the protection unit 30 having a high level of adhesion with the mold unit 40 is included between the first electrode 210 and the second electrode 220. The protection unit 30 prevents the occurrence of an interfacial delamination phenomenon on the surface where the protection unit 30 and the mold unit 40 come in contact with each other (e.g., direct contact with each other).

The protection unit 30 may block the first permeation solder 501 and the second permeation solder 502, which have moved along the interface gap 500 between the first and second electrodes 210 and 220 the mold unit 40. Therefore, the first permeation solder 501 and the second permeation solder 502 may be prevented from being in direct contact with each other. Thus, the first electrode 210 and the second electrode 220 may be prevented from being short-circuited.

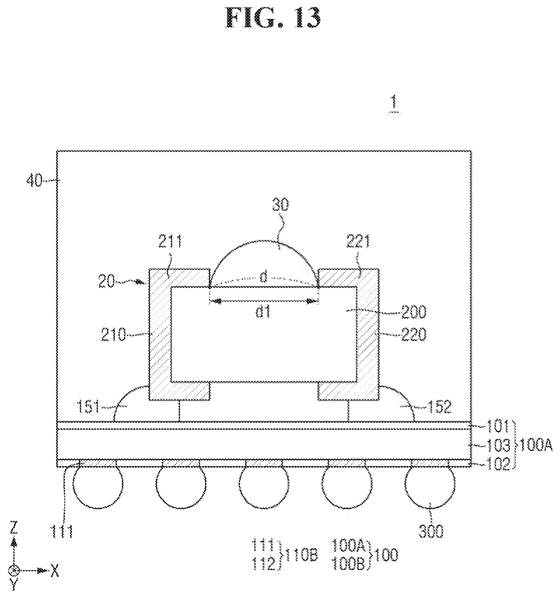

Referring to FIG. 13, the protection unit 30 may be disposed between the first upper area 211 and the second upper area 221 of the ceramic electronic component 20.

The length between the first upper area 211 and the second upper area 221 corresponds to d1. The length of the lower surface of the protection unit 30 corresponds to ‘d’.

In some embodiments, the size of ‘d’ may be the same as that of d1. For example, the length of the lower surface of the protection unit 30 may be the same as the length between the first upper area 211 and the second upper area 221. Therefore, the protection unit 30 may entirely cover the upper surface of the main body 200 of the ceramic electronic component 20 that is in contact with the mold unit 40.

In some embodiments, the protection unit 30 may have a shape that is not in direct contact with a side, which faces the second upper area 221, among sides of the uppermost portion of the first upper area 211. For example, the protection unit 30 may be spaced apart from an inner side of the first upper area 211 which faces the second upper area 221.

Also, in some embodiments, the protection unit 30 may have a shape that is not in direct contact with a side, which faces the first upper area 211, among sides of the uppermost portion of the second upper area 221. For example, the protection unit 30 may be spaced apart from an inner side of the second upper area 221 which faces the first upper area 211.

In some embodiments, the protection unit 30 may be made of a thermosetting resin such as an epoxy resin. However, embodiments of the present disclosure are not necessarily limited thereto.

Similarly to that described with reference to FIG. 5, in some embodiments, the protection unit 30 having a high level of adhesion with the mold unit 40 is included between the first electrode 210 and the second electrode 220, whereby an interfacial delamination phenomenon may be prevented from occurring on the surface where the protection unit 30 and the mold unit 40 come in contact with each other.

The protection unit 30 may block the first permeation solder 501 and the second permeation solder 502, which have moved along the interface gap 500 between the first and second electrodes 210 and 220 and the mold unit 40. Therefore, the protection unit 30 may prevent the first permeation solder 501 and the second permeation solder 502 from being in direct contact with each other. Thus, the first electrode 210 and the second electrode 220 may be prevented from being short-circuited.

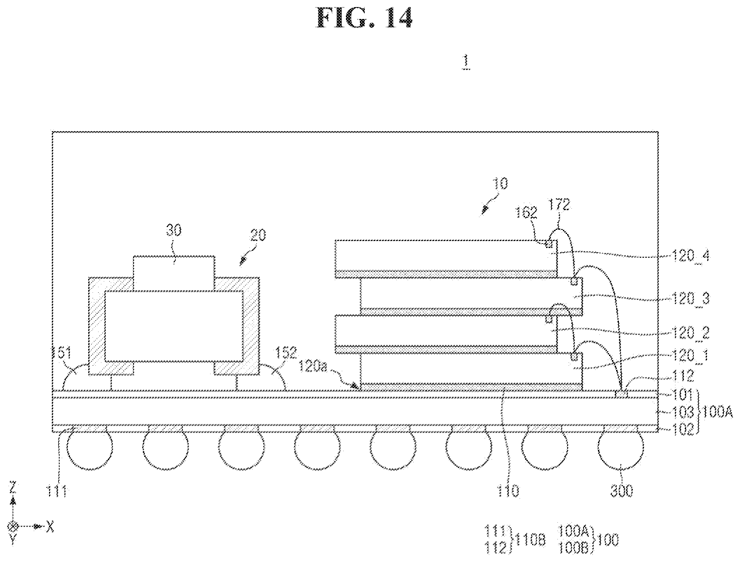

FIG. 14 is a view illustrating only some elements of a semiconductor package according to an embodiment of the present disclosure.

Referring to FIG. 14, a semiconductor package 1 according to an embodiment of the present disclosure may include a substrate 100, a semiconductor chip stack 10 including a plurality of semiconductor chips 120_1 to 120_4, a ceramic electronic component 20 and a mold unit 40.

In FIG. 14, the numbers of the semiconductor chip stacks 10 and the ceramic electronic components 20 are shown as one. However, embodiments of the present disclosure are not necessarily limited thereto. For example, in some embodiments the semiconductor package 1 may include a plurality of semiconductor chip stacks 10 and a plurality of ceramic electronic components 20.

The upper wiring pad 112 may be disposed in the upper passivation layer 101. The lower wiring pad 111 may be disposed in the lower passivation layer 102.

The upper wiring pad 112 may serve to electrically connect the semiconductor chip stack 10 with the package substrate 100. For example, in an embodiment the upper wiring pad 112 may be connected to a semiconductor chip pad 162 of the semiconductor chip stack 10 through a connector 172. For example, in an embodiment the connector 172 may be a bonding wire.

The lower wiring pad 111 may be disposed below the insulating layer 103. The lower wiring pad 111 may be electrically connected to the external connection terminal 300. The lower wiring pad 111 may serve to electrically connect the external connection terminal 300 with the package substrate 100.

The numbers of the upper wiring pads 112 and the lower wiring pads 111 are necessarily limited to those shown in FIG. 14. For example, in some embodiments the numbers of the upper wiring pads 112 and the lower wiring pads 111 may be different from those shown in FIG. 14.

The upper wiring pad 112 and the lower wiring pad 111 may include a conductive material. In an embodiment, the upper wiring pad 112 and the lower wiring pad 111 may include, for example, gold (Au), silver (Ag), copper (Cu), nickel (Ni) or aluminum (Al). However, embodiments of the present disclosure are not necessarily limited thereto.

The semiconductor chip stack 10 may include a plurality of semiconductor chips 120_1 to 120_4. For example, the semiconductor chip stack 10 may have a form in which a plurality of semiconductor chips (e.g., 120_1 to 120_4) are consecutively stacked in the third direction Z.

The semiconductor chips 120_1 to 120_4 may include a memory chip. In an embodiment, each of the semiconductor chips 120_1 to 120_4 may include, for example, a volatile memory chip such as a DRAM.

The semiconductor chip pad 162 may be disposed on an upper surface of each of the semiconductor chips 120_1 to 120_4. The semiconductor chip pad 162 may be exposed on one edge (e.g., a right edge in the X direction) of an upper surface of each of the semiconductor chips 120_1 to 120_4. The semiconductor chip pad 162 may be formed as a plurality of semiconductor chip pads 162.

In an embodiment, the semiconductor chip pad 162 may include at least one metal of, for example, copper (Cu), aluminum (Al), tungsten (W) or titanium (Ti).

In an embodiment, the semiconductor chip pad 162 may be protruded upwardly from each of the semiconductor chips 120_1 to 120_4 and an upper surface of the semiconductor chip pad 162 may not be disposed on a same plane (e.g., in the Z direction) as an upper surface of each of the semiconductor chips 120_1 to 120_4. However, embodiments of the present disclosure are not necessarily limited thereto. For example, in an embodiment a via may be formed instead of the semiconductor chip pad 161. In this embodiment, the semiconductor chips 120_1 to 120_4 may be electrically connected to the package substrate 100 through the via.

In an embodiment, an adhesive layer 120a may be disposed between the semiconductor chips 120_1 to 120_4 (e.g., in the Z direction) and between the lowermost semiconductor chip 120_1 and the package substrate 100.

In an embodiment, the adhesive layer 120a may be, for example, a direct adhesive film (DAF). The adhesive layer 120a may include an insulating polymer. For example, the adhesive layer 120a may include an epoxy-based resin and a filler.

In an embodiment, the filler may be at least one selected from the group consisting of silica (SiO₂), alumina (Al₂O₃), silicon carbide (SiC), barium sulfate (BaSO₄), talc, pearl, mica powder, aluminum hydroxide (AlOH₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃) and calcium zirconate (CaZrO₃). However, embodiments of the present disclosure are not necessarily limited thereto and the material of the filler may vary. For example, in an embodiment the filler may include a metal material and/or an organic material.

The adhesive layer 120a may serve to insulate one of the semiconductor chips 120_1 to 120_4 from another one. In addition, the adhesive layer 120a may serve to insulate any one of the semiconductor chips 120_1 to 120_4 from the package substrate 100.

In some embodiments, sidewalls of each of the semiconductor chips 120_1 to 120_4 included in the semiconductor chip stack 10 may be aligned with each other. For example, the sidewalls of any one of the semiconductor chips 120_1 to 120_4 may be disposed on the same line as those of another one 120_2 along the third direction Z.

In some embodiments, the semiconductor chips 120_1 to 120_4 included in the semiconductor chip stack 10 may be stacked in a stepped shape. For example, any one 120_1 of the semiconductor chip stack 10 may be stacked in a state that it is spaced apart from another one 120_2 at a predetermined distance in the first direction X or the second direction Y. In addition, any one 120_3 of the semiconductor chip stack 10 may be stacked in a state that it is spaced apart from another one 120_4 at a predetermined distance in the first direction X or the second direction Y.

In some embodiments, the semiconductor chips 120_1 to 120_4 included in the semiconductor chip stack 10 may be stacked in a zigzag shape. The first and second semiconductor chips 120_1 and 120_2 may not be aligned with the third and fourth semiconductor chips 120_3 and 120_4 along the third direction Z. For example, the first and second semiconductor chips 120_1 and 120_2 may be alternately disposed, and the third and fourth semiconductor chips 120_3 and 120_4 may be alternately disposed.

In this embodiment, the first and third semiconductor chips 120_1 and 120_3 and the second and fourth semiconductor chips 120_2 and 120_4, which are included in the semiconductor chip stack 10, may be aligned along the third direction Z, respectively.

In an embodiment, the semiconductor chips 120_1 to 120_4 may include a memory chip. The semiconductor chips 120_1 to 120_4 may include, for example, a nonvolatile memory chip such as a NAND flash memory.

The mold unit 40 may integrally cover the semiconductor chip stack 10, the protection unit 30 and the ceramic electronic component 20. The mold unit 40 may be disposed on the upper surface of the semiconductor chip stack 10, the upper surface of the protection unit 30 and the upper surface of the ceramic electronic component 20. The mold unit 40 may be in direct contact with the upper surface of the semiconductor chip stack 10, the upper surface of the protection unit 30 and the upper surface of the ceramic electronic component 20, respectively.

The mold unit 40 may include an insulating material. For example, in an embodiment the mold unit 40 may include a thermosetting resin such as an epoxy resin and a thermoplastic resin such as polyimide. In addition, for example, the mold unit 40 may include a molding material such as an Epoxy Molding Compound (EMC). However, embodiments of the present disclosure are not necessarily limited thereto.

FIG. 15 is a block diagram illustrating a semiconductor package according to an embodiment of the present disclosure.

Referring to FIG. 15, the package substrate 100 may include a first area A1 and a second area A2 spaced apart from the first area A1 in the first direction X when viewed in a plan view. The first semiconductor chip stack 10 and the second semiconductor chip stack 10 may be spaced apart from each other on the package substrate 100. For example, the second semiconductor chip stack 10 may be spaced apart from the first semiconductor chip stack 10 in the first direction X.

The second semiconductor chip stack 10 may be formed in the second area A2 in which the first semiconductor chip stack 10 is not disposed. In an embodiment, the second semiconductor chip stack 10 may include a plurality of semiconductor chips. For example, the second semiconductor chip stack 10 may have a shape in which the plurality of semiconductor chips are stacked in the third direction Z.

The first area A1 and the second area A2 may be areas in which the first semiconductor chip stack 10 and the second semiconductor chip stack 10 are disposed, respectively, and the third area A3 and the fourth area A4 may be areas in which the first ceramic electronic component 20 and the second ceramic electronic component 20 are disposed, respectively.

A controller 50 for controlling the first semiconductor chip stack 10 and the second semiconductor chip stack 10 may be disposed between the third area A3 and the fourth area A4. In an embodiment, the controller 50 may be, for example, a logic chip for controlling a memory chip.

Referring to FIGS. 2, 3 and 15, in some embodiments, the tape type protection unit 30 may be attached to the first ceramic electronic component 20 by the fabricating method of FIG. 2. In addition, a non-conductive material, such as a thermosetting resin, for example, an epoxy resin may be coated on the second ceramic electronic component 20 in the form of a paste by the fabricating method of FIG. 3. However, embodiments of the present disclosure are not necessarily limited thereto. For example, in an embodiment a thermosetting resin such as an epoxy resin may be coated on the first ceramic electronic component 20 in the form of a paste, and the tape type protection unit 30 may be attached to the second ceramic electronic component 20. In an embodiment, the tape type protection unit 30 may be attached to all of the first and second ceramic electronic components 20, or a paste type protection unit 30 may be coated thereon.

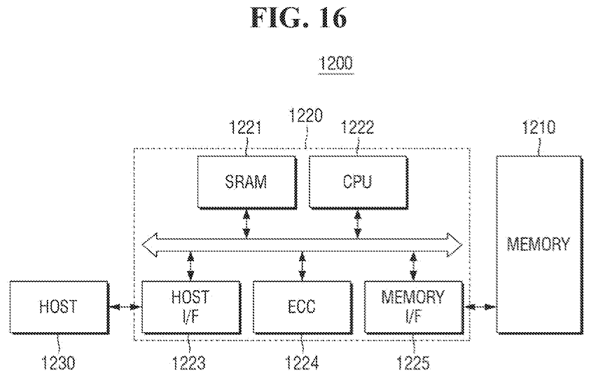

FIG. 16 is a block diagram illustrating a memory card including a semiconductor package according to an embodiment of the present disclosure.

Referring to FIG. 16, the semiconductor package according to an embodiment of the present disclosure may be applied to a memory card 1200.

In an embodiment, the memory card 1200 may include a memory controller 1220 for controlling data exchange between a host 1230 and a memory 1210. An SRAM 1221 may be used as a working memory of a central processing unit 1222. The host interface 1223 may include a data exchange protocol of the host 1230 connected to the memory card 1200. An error correction code 1224 may detect and correct errors included in data read from the memory 1210. The memory interface 1225 may interface with the memory 1210. The central processing unit 1222 may perform overall control operations for data exchange of the memory controller 1220.

For example, in an embodiment at least one of the memory 1210 or the central processing unit 1222 may include at least one of the semiconductor packages according to some embodiments of the present disclosure.

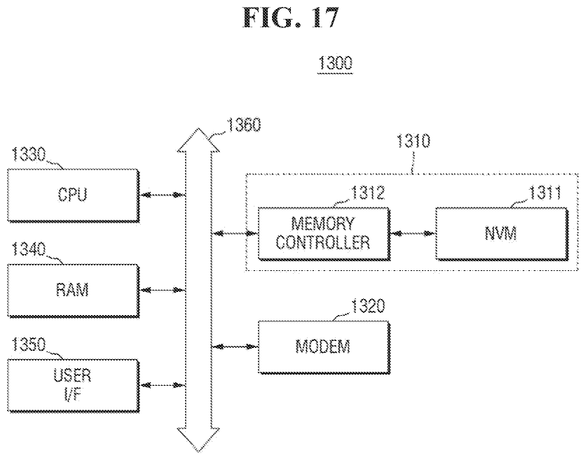

FIG. 17 is a block diagram illustrating an information processing system to which a semiconductor package according to some embodiments of the present disclosure is applied.

Referring to FIG. 17, the semiconductor package according to some embodiments of the present disclosure may be applied to an information processing system 1300.

The information processing system 1300 may include a mobile device or a computer. For example, in an embodiment the information processing system 1300 may include a memory system 1310, a modem 1320, a central processing unit (CPU) 1330, a RAM 1340 and a user interface 1350, which are electrically connected to a system bus 1360. The memory system 1310 includes a memory 1311 and a memory controller 1312, and may be configured to be substantially the same as the memory card 1200 of FIG. 16. In addition, at least one of the central processing unit 1330 or the RAM 1340 may include at least one of the semiconductor packages according to some embodiments of the present disclosure.

Data processed by the CPU 1330 or data input from the outside may be stored in the memory system 1310. In an embodiment, the information processing system 1300 may be provided as a memory card, a solid state disk, a camera image processor and other application chipset. For example, the memory system 1310 may be configured as a solid state disk (SSD). In this embodiment, the information processing system 1300 may stably and reliably store a large amount of data in the memory system 1310.

Although non-limiting embodiments of the present disclosure have been described with reference to the accompanying drawings, it will be apparent to those skilled in the art that the present disclosure can be fabricated in various forms without being limited to the above-described embodiments and can be embodied in other specific forms without departing from the technical spirits and essential characteristics of the present disclosure. Thus, the above embodiments are to be considered in all respects as illustrative and not restrictive.

What is claimed is:

1. A semiconductor package comprising:
a package substrate;
a ceramic electronic component electrically connected to the package substrate, the ceramic electronic component including a main body having a main body upper surface, a first electrode disposed on a first side of the main body, the first side of the main body including a first upper area disposed on the main body upper surface, and a second electrode disposed on a second side of the main body that is opposite to the first side of the main body, the second side of the main body including a second upper area disposed on the main body upper surface, the second upper area is spaced apart from the first upper area;
a protection unit disposed on the main body upper surface and positioned between the first upper area and the second upper area; and
a mold unit sealing the ceramic electronic component and the protection unit.

2. The semiconductor package of claim 1, wherein a length of a lowermost portion of the protection unit is less than or equal to a distance between the first upper area and the second upper area.

3. The semiconductor package of claim 2, wherein the protection unit covers at least a portion of an upper surface of the first upper area.

4. The semiconductor package of claim 3, wherein the protection unit covers at least a portion of an upper surface of the second upper area.

5. The semiconductor package of claim 2, wherein sides of an uppermost portion of the first electrode are not in direct contact with the protection unit.

6. The semiconductor package of claim 5, wherein sides of an uppermost portion of the second electrode are not in direct contact with the protection unit.

7. The semiconductor package of claim 2, wherein:
the first electrode is connected to the package substrate through a first solder and the second electrode is connected to the package substrate through a second solder;
a first gap is positioned between the first electrode and the mold unit and a second gap is positioned between the second electrode and the mold unit; and
a first permeation solder generated from the first solder and extending along the first gap and a second permeation solder generated from the second solder and extending along the second gap are not in direct contact with each other.

8. The semiconductor package of claim 7, wherein the protection unit blocks the first permeation solder from directly contacting the second permeation solder.

9. The semiconductor package of claim 7, wherein a height of the protection unit is twice or more greater than a height of the first upper area and the second upper area.

10. The semiconductor package of claim 1, wherein the ceramic electronic component is a multi-layer ceramic capacitor.

11. A method for fabricating a semiconductor package, the method comprising:
disposing a first semiconductor chip in a first area of a package substrate;
disposing a second semiconductor chip in a second area of the package substrate, the second area of the package substrate is spaced apart from the first area of the package substrate;
disposing a first multi-layer ceramic capacitor in a third area of the package substrate, the third area of the package substrate is spaced apart from the first and second areas of the package substrate;
disposing a second multi-layer ceramic capacitor in a fourth area of the package substrate, the fourth area of the package substrate is spaced apart from the first to third areas of the package substrate;
disposing a first protection unit on an upper surface of the first multi-layer ceramic capacitor;
disposing a second protection unit on an upper surface of the second multi-layer ceramic capacitor; and
generating a mold unit sealing the first multi-layer ceramic capacitor, the second multi-layer ceramic capacitor, the first semiconductor chip, the second semiconductor chip, the first protection unit and the second protection unit.

12. The method of claim 11, wherein the disposing of the first protection unit on the upper surface of the first multi-layer ceramic capacitor includes attaching a tape type non-conductive material on the upper surface of the first multi-layer ceramic capacitor.

13. The method of claim 11, wherein the disposing the first protection unit on the upper surface of the first multi-layer ceramic capacitor includes coating a non-conductive material on the upper surface of the first multi-layer ceramic capacitor by a dispenser.

14. The method of claim 13, wherein the disposing the second protection unit on the upper surface of the second multi-layer ceramic capacitor includes attaching a tape type non-conductive material on the upper surface of the second multi-layer ceramic capacitor.

15. A semiconductor package comprising:
a package substrate;
a ceramic electronic component electrically connected to the package substrate, the ceramic electronic component including a main body having a main body upper surface, a first electrode disposed on a first side of the main body, the first side of the main body including a first upper area positioned on the main body upper surface, and a second electrode disposed on a second side of the main body that is opposite to the first side of the main body, the second side of the main body including a second upper area positioned on the main body upper surface, the second upper area is spaced apart from the first upper area;
at least one semiconductor chip;
a protection unit disposed on the main body upper surface and positioned between the first upper area and the second upper area; and
a mold unit sealing the ceramic electronic component and the protection unit.

16. The semiconductor package of claim 15, further comprising a controller disposed on the package substrate, the controller controls the semiconductor chip.

17. The semiconductor package of claim 15, wherein a length of a lowermost portion of the protection unit is less than or equal to a distance between the first upper area and the second upper area.

18. The semiconductor package of claim 17, wherein a height of the protection unit is twice or more greater than a height of the first upper area and the second upper area.

19. The semiconductor package of claim 17, wherein the protection unit covers at least a portion of an upper surface of the first upper area.

20. The semiconductor package of claim 17, wherein sides of an uppermost portion of the first electrode and sides of an uppermost portion of the second electrode are not in direct contact with the protection unit.
